(19) United States
(12) Patent Application Publication
(10) Pub. No.: US 2013/0329386 A1
(43) Pub. Date: Dec. 12, 2013

(54) PACKAGE CARRIER AND MANUFACTURING METHOD THEREOF

(71) Applicants: Chin-Sheng Wang, Hsinchu County (TW); Wei-Lun Tai, Hsinchu County (TW)

(72) Inventors: Chin-Sheng Wang, Hsinchu County (TW); Wei-Lun Tai, Hsinchu County (TW)

(73) Assignee: SUBTRON TECHNOLOGY CO. LTD., Hsinchu (TW)

(21) Appl. No.: 13/594,876

(22) Filed: Aug. 27, 2012

(30) Foreign Application Priority Data
Jun. 7, 2012 (TW) 101120523

(51) Int. Cl. H05K 7/06; C25D 5/02; H05K 3/00

(52) U.S. Cl. 361/760; 216/20; 205/118

(57) ABSTRACT

A manufacturing method of a package carrier is provided. A supporting plate is provided, wherein a metal layer is already disposed on the supporting plate. A patterned dry film layer is formed on the metal layer. A portion of the metal layer is exposed by the patterned dry film layer. The patterned dry film layer is used as an electroplating mask to electroplate a surface treatment layer on the portion of the metal layer exposed by the patterned dry film layer. The patterned dry film layer is removed so as to expose the portion of the metal layer. The surface treatment layer is used as an etching mask to etch the portion of the metal layer not covered by the surface treatment layer so as to form a patterned metal layer.

### CROSS-REFERENCE TO RELATED APPLICATION

This application claims the priority benefit of Taiwan application serial no. 101120523, filed on Jun. 7, 2012. The entirety of the above-mentioned patent application is hereby incorporated by reference herein and made a part of this specification.

### BACKGROUND OF THE INVENTION

1. Field of the Invention

The invention relates to a package structure and a manufacturing method thereof. More particularly, the invention relates to a package carrier and a manufacturing method thereof.

2. Description of Related Art

A chip package aims at providing proper signal transmission paths and heat dissipation paths as well as protecting the chip structure. A leadframe serving as a carrier of a chip is frequently employed in a conventional wire bonding technique. As contact density in a chip gradually increases, the leadframe which is unable to satisfy current demands on the high contact density is replaced by a package carrier which can achieve favorable contact density. The chip is packaged onto the package carrier by conductive media, such as conductive wires or bumps.

Generally, the fabrication of the package carrier uses the core as core material, and the patterned circuit layers and the patterned dielectric layers are interleavedly stacked on the core by means of a fully additive process, a semi-additive process, a subtractive process or another process. Consequently, the core takes up a relative great proportion of the whole thickness of the package carrier. Thus, if the thickness of the core can not be effectively reduced, it will be hard for the whole thickness of the stacked package structure to be reduced.

### SUMMARY OF THE INVENTION

The invention provides a package carrier, adapted to carry a chip.

The invention provides a method of manufacturing a package carrier, adapted to manufacture the aforementioned package carrier.

The invention provides a method of manufacturing a package carrier. The method includes the following steps. A supporting plate is provided. A metal layer is already disposed on the substrate. A patterned dry film layer is formed on the metal layer. A portion of the metal layer is exposed by the patterned dry film layer. The patterned dry film layer is used as an electroplating mask to electroplate a surface treatment layer on the portion of the metal layer exposed by the patterned dry film layer. The patterned dry film layer is removed so as to expose the portion of the metal layer. The surface treatment layer is used as an etching mask to etch the portion of the metal layer not covered by the surface treatment layer, so as to form a patterned metal layer.

In an embodiment of the invention, the step of forming the supporting plate includes providing two metal layers. One metal layer is partially combined onto the other metal layer through an adhesive. Next, a conductive layer is respectively formed on the metal layer. Subsequently, an adhesive layer and an insulating layer above the adhesive layer are pressed on the conductive layer. Finally, the adhesive is removed, so as to form two independent supporting plates each with a metal layer. Each supporting plate includes an insulating layer, an adhesive layer, and a conductive layer sequentially stacked. The metal layer is located on the conductive layer.

In an embodiment of the invention, a material of the conductive layer includes nickel.

In an embodiment of the invention, a method of forming the conductive layer includes electroplating.

In an embodiment of the invention, a material of the surface treatment layer includes nickel or silver.

The invention provides a package carrier, adapted to carry a chip. The package carrier includes a supporting plate, a patterned metal layer, and a surface treatment layer. The supporting plate has a top surface. The patterned metal layer is disposed on the supporting plate, and exposes a portion of the top surface. The surface treatment layer is disposed on the patterned metal layer, wherein a chip is disposed on the surface treatment layer and is electrically connected to the surface treatment layer.

In an embodiment of the invention, the supporting plate includes an insulating layer, an adhesive layer, and a conductive layer sequentially stacked. The patterned metal layer is disposed on the conductive layer, and exposes a portion of the conductive layer.

In an embodiment of the invention, a material of the surface treatment layer includes nickel or silver.

In an embodiment of the invention, the chip is electrically connected to the surface treatment layer through wire bonding.

In an embodiment of the invention, the chip is electrically connected to the surface treatment layer through flip chip bonding.

Based on the above, the package carrier of the invention uses a patterned metal layer and a surface treatment layer, to make up a die pad to place a chip and a bonding pad for electrical connection. After the molding process for completing the chip, the supporting plate is removed, so as to form a thinner package structure.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A to FIG. 1G are schematic cross-sectional views of a method of manufacturing a package carrier according to an embodiment of the invention.

FIG. 2A to FIG. 2C are schematic cross-sectional views of the manufacturing steps of the package carrier depicted in FIG. 1G carries a chip.

FIG. 3 is a schematic cross-sectional view of the package carrier depicted in FIG. 1G carries a chip.

### DESCRIPTION OF EMBODIMENTS

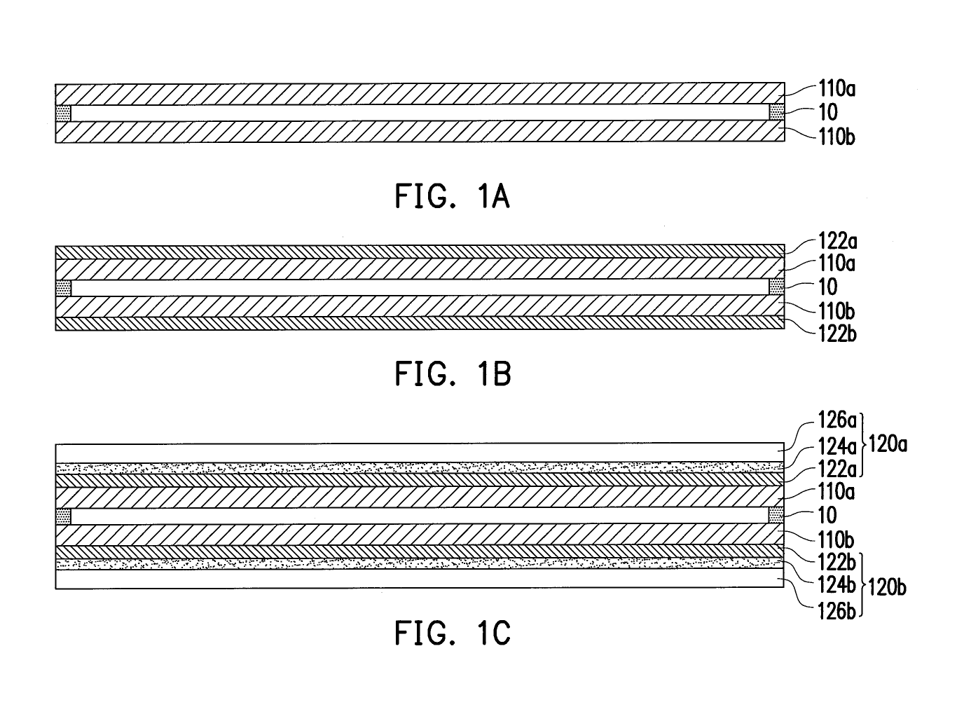

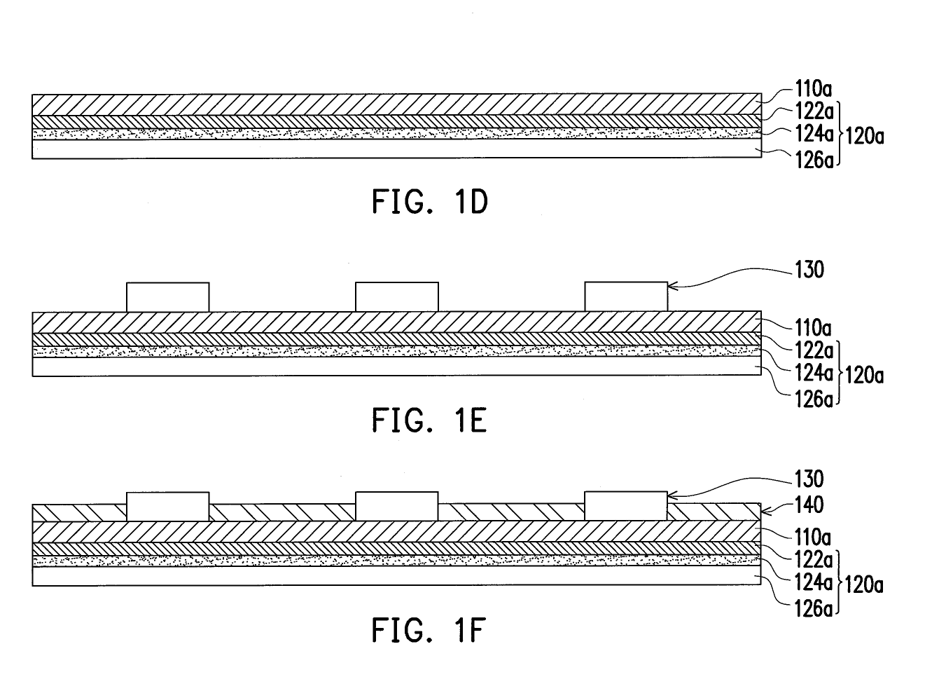

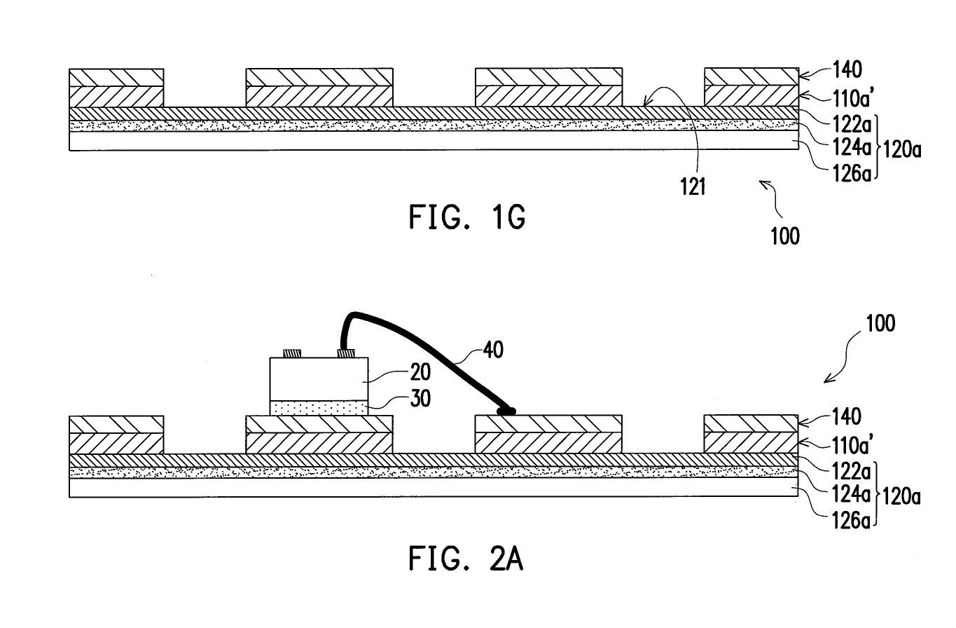

FIG. 1A to FIG. 1G are schematic cross-sectional views of a method of manufacturing a package carrier according to an embodiment of the invention. Referring to FIG. 1D, according to the method of manufacturing a package carrier of the embodiment, first a supporting plate 120a is provided, wherein a metal layer 110a is already disposed on the supporting plate 120a.

Specifically, the steps of forming the supporting plate 120a are detailed below. First, please refer to FIG. 1A. Two metal layers 110a, 110b are provided. The metal layer 110a is partially combined onto the metal layer 110b through an adhesive 10. A material of the metal layer 110a includes copper, aluminum, silver, gold, or other metals with high conductivity. Next, referring to FIG. 1B, a conductive layer 122a is formed on the metal layer 110a, and the metal layer 110b is formed on a conductive layer 122b. Herein, the method of forming the conductive layer 122a and 122b includes electroplating, and the material of the conductive layers 122a and 122b is, for example, nickel. Next referring to FIG. 1C, an adhesive layer 124a and an insulating layer 126a above the adhesive layer 124a are pressed on the conductive layer 122a. An adhesive layer 124b and an insulating layer 126b above the adhesive layer 124b are pressed on the conductive layer 122b. The material of the insulating layers 126a and 126b is, for example, glass fiber resin. Herein, the insulating layer 126a, the adhesive layer 124a, and the conductive layer 122a make up a supporting plate 120a. The insulating layer 126b, the adhesive layer 124b, and the conductive layer 122b make up another supporting plate 120b. Finally, please refer to FIG. 1D. The adhesive 10 is removed, so as to form two independent supporting plates 120a (or 120b) each with a metal layer 110a (or 110b). The supporting plate 120a includes an insulating layer 126a, an adhesive layer 124a, and a conductive layer 122a sequentially stacked. The metal layer 110a is located on the conductive layer 122a, and exposes a portion of the conductive layer 122a. Thereby, the fabrication of the supporting plate 120a and the metal layer 110a thereof is completed.

It should be noted that the embodiment uses a symmetrical method of forming the two supporting plates 120a, 120b, and the metal layers 110a, 110b thereof. Thus, when pressing the adhesive layers 124a, 124b and the insulating layers 126a, 126b on the metal layers 110a, 110b, the problem of the structure warping after pressing is effectively avoided. Furthermore, since the embodiment uses a symmetrical method of forming the two supporting plates 120a, 120b, and the metal layers 110a, 110b thereof, thus, after separating the plates (i.e. after removing the adhesive 10), two independent structures can be simultaneously obtained, effectively reducing manufacturing time, and raising production.

Next, referring to FIG. 1E, a patterned dry film layer 130 is formed on the metal layer 110a, wherein the patterned dry film layer 130 exposes a portion of the metal layer 110a.

Then, referring to FIG. 1F, the patterned dry film layer 130 is used as an electroplating mask to electroplate a surface treatment layer 140 on the portion of the metal layer 110a exposed by the patterned dry film layer 130. Herein, a material of the surface treatment layer 140 is, for example, nickel or silver.

Finally, referring to FIG. 1G, the patterned dry film layer 130 is removed so as to expose portions of the metal layer 110a. Next, the surface treatment layer 140 is used as an etching mask to etch the portion of the metal layer 110a not covered by the surface treatment layer 140, so as to form a patterned metal layer 110a′. Herein, the fabrication of the package carrier 100 is completed.

Structurally, please refer to FIG. 1G. The package carrier 100 includes a supporting plate 120a, a patterned metal layer 110a′, and a surface treatment layer 140. The supporting plate 120a includes an insulating layer 126a, an adhesive layer 124a, and a conductive layer 122a, sequentially stacked, and the supporting plate 120a includes a top surface 121. The patterned metal layer 110a′ is disposed on the supporting plate 120a, and exposes a portion of the top surface 121. The patterned metal layer 110a′ is located on the conductive layer 122a, and exposes a portion of the conductive layer 122a. The surface treatment layer 140 is disposed on the patterned metal layer 110a′, wherein a material of the surface treatment layer 140 is, for example, nickel or silver.

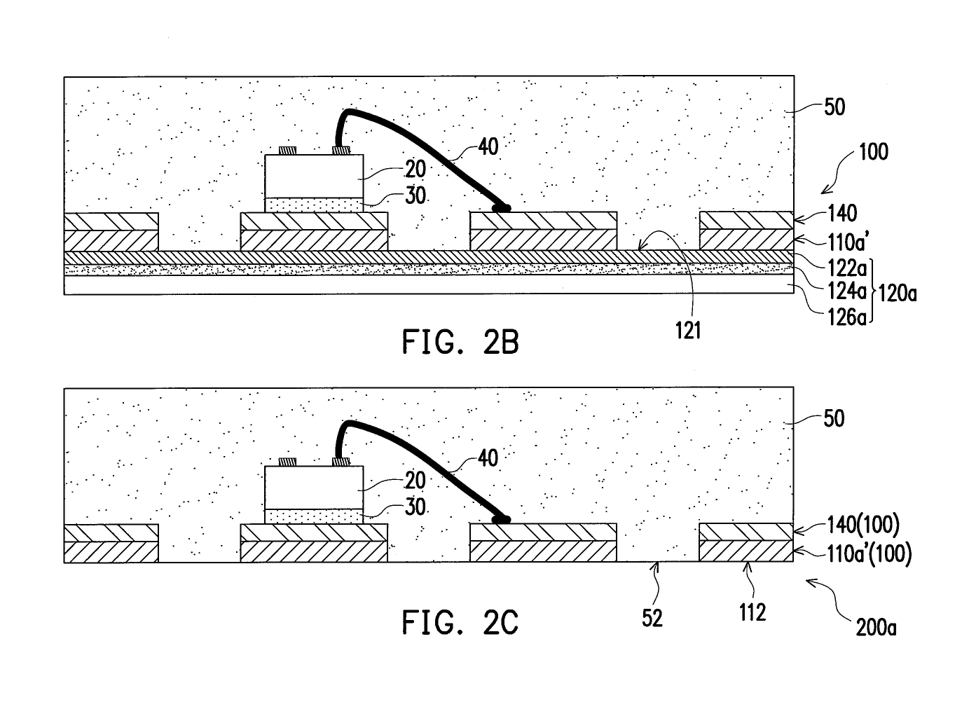

FIG. 2A to FIG. 2C are schematic cross-sectional views of the manufacturing steps of the package carrier depicted in FIG. 1G carries a chip. Referring to FIG. 2A, in the embodiment, the package carrier 100 is adapted to carry a chip 20. The chip 20 is disposed on the surface treatment layer 140 above the patterned metal layer 110a′ through an adhesive layer 30. The chip 20 is electrically connected to the surface treatment layer 140 through a bonding wire 40. That is to say, the chip 20 of the embodiment is electrically connected to the surface treatment layer 140 through wire bonding. Herein, the chip 20 is, for example, an integrated circuit chip. The integrated circuit chip is, for example, a single chip such as a graphics chip or a memory chip, or a chip module or an LED chip.

Next, referring to FIG. 2B, a molding process is performed, so as to form a molding compound 50 on the package carrier 100. The molding compound 50 encapsulates the chip 20, the adhesive layer 30, the bonding wire 40, the surface treatment layer 140 and the patterned metal layer 110a′ of the package carrier 100. The molding compound 50 covers a portion of the top surface 121 of the supporting plate 120a.

Finally, referring to FIG. 2C, the supporting plate 120a of the package carrier 100 is removed, to expose a bottom surface 112 of the patterned metal layer 110a′. A bottom surface 52 of the molding compound 50 is substantially aligned with the bottom surface 112 of the patterned metal layer 110a′. Herein, the fabrication of the package structure 200a is complete. The package structure 200a is, for example, a quad flat no-lead (QFN) package structure.

The package carrier 100 of the embodiment uses a patterned metal layer 110a′ and a surface treatment layer 140 to make up a die pad (i.e. location of the chip 20) to place a chip 20 and a bonding pad (i.e. the placement location of the bonding wire 40) for electrical connection. After the molding process for completing the chip 20, the supporting plate is removed 120a, so as to form the package structure 200a. That is to say, the supporting plate 120a is removed after the molding process, so that all that is left of the package carrier 100 of the package structure 200a is the patterned metal layer 110a′ and the surface treatment layer 140. Thus, compared to conventional way where the patterned circuit layers and the patterned dielectric layers are interleavedly stacked on the core to form the package carrier, the present embodiment adapts a package carrier 100 where the subsequently completed package structure 200a has a thinner package thickness. Further, since the chip 20 is disposed on the surface treatment layer 140, the heat generated by the chip 20 is rapidly transmitted to an external environment through the surface treatment layer 140 and the patterned metal layer 110a′ made of metal material. Not only does this improve the efficiency and life span of the chip 20, the heat dissipation effect of the package structure 200a is also improved.

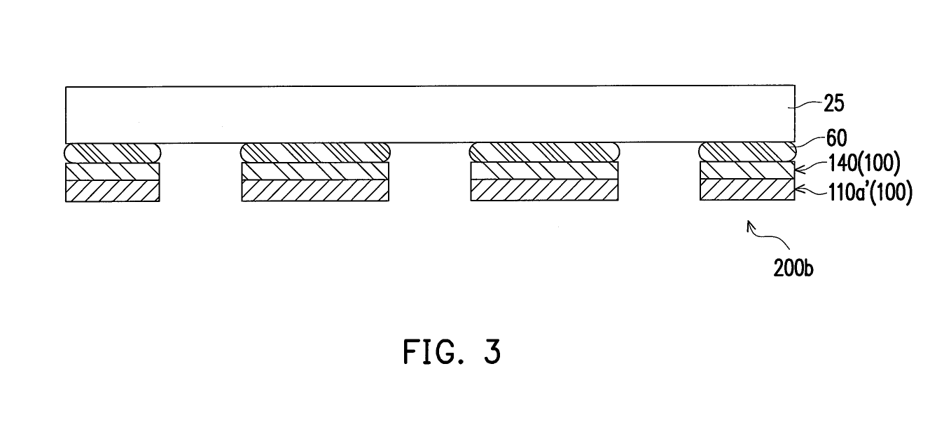

It should be noted that the invention does not limit the combination of a chip 20 and a package carrier 100, even though herein the chip 20 is electrically connected to the surface treatment layer 140 of the package carrier 100 through wire bonding. In another embodiment, referring to FIG. 3, a chip 25 can have a plurality of bumps 60 so as to electrically connect to the surface treatment layer 140 through flip chip bonding. That is to say, the aforementioned combination of the chip 20 and the package carrier 100 are merely exemplary, and the invention is not limited thereto.

To sum up, the package carrier of the invention uses a patterned metal layer and a surface treatment layer, to make up a die pad to place a chip and a bonding pad for electrical connection. After the molding process for completing the chip, the supporting plate is removed, so as to form a thinner package structure.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A method of manufacturing a package carrier, comprising:
providing a supporting plate, wherein a metal layer is already disposed on the supporting plate;
forming a patterned dry film layer on the metal layer, wherein a portion of the metal layer is exposed by the patterned dry film layer;
electroplating a surface treatment layer on the portion of the metal layer exposed by the patterned dry film layer by utilizing the patterned dry film layer as an electroplating mask;
removing the patterned dry film layer so as to expose the portion of the metal layer; and
etching the portion of the metal layer not covered by the surface treatment layer by utilizing the surface treatment as an etching mask, so as to form a patterned metal layer.

2. The method of manufacturing the package carrier as claimed in claim 1, wherein the step of forming the supporting plate comprises:
providing two of the metal layers, one of the metal layers is partially combined onto the other metal layer through an adhesive;
respectively forming a conductive layer on each of the metal layers;
respectively pressing an adhesive layer and an insulating layer above the adhesive layer on each of the conductive layers; and
removing the adhesive, so as to form two independent supporting plates each with the metal layer, wherein each supporting plate includes the insulating layer, the adhesive layer, and the conductive layer sequentially stacked, and the metal layer is located on the conductive layer.

3. The method of manufacturing the package carrier as claimed in claim 2, wherein a material of the conductive layer comprises nickel.

4. The method of manufacturing the package carrier as claimed in claim 2, wherein a method of forming the conductive layers comprises electroplating.

5. The method of manufacturing the package carrier as claimed in claim 1, wherein the material of the surface treatment layer comprises nickel or silver.

6. A package carrier, adapted to carry a chip, the package carrier comprising:
a supporting plate, having a top surface;
a patterned metal layer, disposed on the supporting plate, and exposing a portion of the top surface; and
a surface treatment layer, disposed on the patterned metal layer, wherein the chip is disposed on the surface treatment layer and is electrically connected to the surface treatment layer.

7. The package carrier as claimed in claim 6, wherein the supporting plate includes an insulating layer, an adhesive layer, and a conductive layer sequentially stacked, the patterned metal layer is disposed on the conductive layer, and exposes a portion of the conductive layer.

8. The package carrier as claimed in claim 6, wherein the material of the surface treatment layer comprises nickel or silver.

9. The package carrier as claimed in claim 6, wherein the chip is electrically connected to the surface treatment layer through wire bonding.

10. The package carrier as claimed in claim 6, wherein the chip is electrically connected to the surface treatment layer through flip chip bonding.
